(19) United States
(12) Patent Application Publication
(10) Pub. No.: US 2026/0057914 A1
(43) Pub. Date: Feb. 26, 2026

(54) MEMORY DEVICE

(71) Applicant: Samsung Electronics Co., Ltd., Suwon-si (KR)

(72) Inventors: Youngseok Park, Suwon-si (KR); Yongjun Kim, Suwon-si (KR); Sanghoon Jung, Suwon-si (KR); Younghun Seo, Suwon-si (KR); Hyunchul Yoon, Suwon-si (KR)

(21) Appl. No.: 19/217,290

(22) Filed: May 23, 2025

(30) Foreign Application Priority Data
Aug. 21, 2024 (KR) 10-2024-0112282

(51) Int. Cl. G11C 5/06; G11C 11/408; G11C 11/4091; G11C 11/4096

(52) U.S. Cl. CPC G11C 5/063; G11C 11/4087; G11C 11/4091; G11C 11/4096

(57) ABSTRACT

A memory device including a memory cell array with word lines extending in a first direction and bit lines extending in a second direction, intersecting the first direction; local input/output lines transmitting a potential transmitted through selected bit lines to bit line sense amplifiers; input/output gate regions including first and second column selection transistors connected to the bit lines and corresponding local input/output line; a plurality of first column selection lines connected to gates of first column selection transistors corresponding to first and second bit line groups and extending in the second direction; a second reference column selection line extending in the first direction and connected to gates of second column selection transistors corresponding to the first bit line group, and; and a second complementary column selection line extending in the first direction and connected to gates of second column selection transistors corresponding to the second bit line group.

### CROSS-REFERENCE TO RELATED APPLICATION(S)

This application claims benefit of priority under 35 U.S. C. 119 to Korean Patent Application No. 10-2024-0112282 filed on Aug. 21, 2024, in the Korean Intellectual Property Office, the disclosure of which is incorporated herein by reference in its entirety.

### BACKGROUND

The present disclosure relates to a memory device.

A memory device such as a Dynamic Random Access Memory (DRAM) includes memory cells connected to word lines and bit lines. The memory device stores data in the memory cells through the bit lines, or reads out data stored in the memory cells. The memory device may transfer data to the bit lines through input/output lines, or may receive data from the bit lines.

Column selection transistors may be connected between the input/output lines and the bit lines, and the column selection transistors may be controlled by column selection signals provided from column selection lines extending by intersecting the memory cell array. As memory cells become more highly integrated, it may be difficult to effectively arrange the plurality of column selection lines in a memory cell array region.

### SUMMARY

An aspect of the present disclosure is to provide a memory device in which column selection lines may be efficiently disposed so that circuits may be highly integrated.

A memory device according to an example embodiment of the present disclosure includes: a memory cell array including a plurality of word lines extending in a first direction and a plurality of bit lines extending in a second direction, intersecting the first direction, and a plurality of memory cells connected to the plurality of word lines and the plurality of bit lines; local input/output lines transmitting a potential transmitted through selected bit lines among the plurality of bit lines to bit line sense amplifiers; input/output gate regions including first and second column selection transistors connected to each of the plurality of bit lines and a corresponding local input/output line among the local input/output lines in series; a plurality of first column selection lines respectively connected to gates of first column selection transistors corresponding to a plurality of bit line groups and extending in the second direction; a second reference column selection line respectively connected to gates of second column selection transistors corresponding to a first bit line group among the plurality of bit line groups, and extending in the first direction; and a second complementary column selection line respectively connected to gates of second column selection transistors corresponding to a second bit line group among the plurality of bit line groups, and extending in the first direction.

A memory device according to example embodiments of the present disclosure includes: a memory cell array region including a plurality of word lines extending in a first direction and a plurality of bit lines extending in a second direction, intersecting the first direction, and a plurality of memory cells connected to the plurality of word lines and the plurality of bit lines; and an input/output gate region for transmitting a potential transmitted through selected bit lines among the plurality of bit lines to local input/output lines, and the input/output gate region includes: a plurality of active regions arranged in the first direction and the second direction; a plurality of first gate structures including a first main pattern spaced apart from the plurality of active regions in the second direction and extending in the first direction, and first finger patterns arranged in the first direction and extending so as to intersect the active regions arranged in the second direction; a plurality of second gate structures including a second main pattern spaced apart in an opposite direction from the first main pattern based on the plurality of active regions and extending in the first direction, and a plurality of second finger patterns respectively extending so as to intersect the active regions arranged in the second direction and adjacent to one first finger pattern in the first direction; a plurality of contacts electrically connecting each of the plurality of bit lines to an active region in a direction opposite to that of the second finger pattern, based on the first finger pattern; a plurality of local input/output lines electrically connected to an active region in a direction opposite to that of the first finger pattern, based on the second finger pattern; a plurality of first column selection lines respectively extending in the second direction and connected to each of the plurality of first gate structures; and a plurality of second column selection lines respectively extending in the first direction and connected to each of the plurality of second gate structures.

A memory device according to example embodiments of the present disclosure includes: a memory cell array including a plurality of word lines extending in a first direction and a plurality of bit lines extending in a second direction, intersecting the first direction, and a plurality of memory cells connected to the plurality of word lines and the plurality of bit lines; and an input/output gate region for transmitting a potential transmitted through selected bit lines among the plurality of bit lines to bit line sense amplifiers, and the input/output gate region includes: a plurality of active regions arranged in the first direction and the second direction; a plurality of first gate structures including a first main pattern extending in the second direction around the plurality of active regions, and first branch patterns connected to the first main pattern and arranged in the second direction and extending so as to intersect the active regions arranged in the first direction; a plurality of second gate structures including a second main pattern extending in the second direction around the plurality of active regions, and a plurality of second finger patterns connected to the second main pattern and extending in the first direction and arranged in the second direction and extending so as to intersect the active regions adjacent to one first branch pattern in the second direction and arranged in the first direction; a plurality of contacts electrically connecting each of the plurality of bit lines to an active region in a direction opposite to that of the second branch pattern, based on the first branch pattern; a plurality of local input/output lines electrically connected to an active region in a direction opposite to that of the first branch pattern, based on the second branch pattern; a plurality of first column selection lines respectively extending in the second direction and connected to each of the plurality of first gate structures; and a plurality of second column selection lines respectively extending in the first direction and connected to each of the plurality of second gate structures.

The branch patterns may include patterns extending in opposite directions based on the first main pattern, and the plurality of second gate structures may be arranged so that two second gate structures surround branch patterns of one first gate structure.

Two adjacent second gate structures among the plurality of second gate structures may share the second main pattern.

A memory device according to example embodiments of the present disclosure includes: a first semiconductor layer including a plurality of memory cell structures respectively including a plurality of word lines extending in a first direction, a plurality of bit lines extending in a second direction, and a plurality of memory cells connected to the plurality of word lines and the plurality of bit lines; and a second semiconductor layer including core circuit regions overlapping the plurality of memory cell structures in a third direction and respectively including sub-word line driver circuits and bit line sense amplifier circuits, word line vias connecting the plurality of word lines and the sub-word line driver circuits, bit line vias connecting the plurality of bit lines and the bit line sense amplifier circuits, a plurality of local input/output lines transmitting a potential transmitted through the memory cell array to the bit line sense amplifiers, and a plurality of column selection switches including first and second column selection transistors connected to each of the plurality of bit lines and a corresponding local input/output line among the local input/output lines in series, and the second semiconductor layer includes; a plurality of first column selection lines connected to the plurality of first column selection transistors and extending in the second direction; and a plurality of second column selection lines connected to the plurality of second column selection transistors and extending in the first direction.

In a memory device according to an example embodiment of the present disclosure, a first and second column selection transistors may be connected in series between one input/output line and one bit line, and the first and second column selection transistors may be controlled according to a first column selection line extending in a column direction and a second column selection line extending in a row direction. Since the column selection lines may be disposed separately in the column direction and the row direction, the flexibility of the memory device design may be improved. Accordingly, the circuits of the memory device may be highly integrated.

The aspects to be solved by the present disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating a memory device according to an example embodiment of the present disclosure;

FIG. 2 is a circuit diagram illustrating a sense amplifier circuit according to an example embodiment of the present disclosure;

FIG. 3 is a block diagram illustrating a memory device according to an example embodiment of the present disclosure;

FIG. 4 is a view illustrating an arrangement structure of bit line sense amplifiers according to an example embodiment of the present disclosure;

FIG. 5 is a view illustrating a connection structure of bit lines and local input/output lines according to an example embodiment of the present disclosure;

FIG. 6 is an arrangement diagram of an input/output gate circuit according to an example embodiment of the present disclosure;

FIG. 7 is a cross-sectional view taken along line I-I′ of FIG. 6;

FIG. 8 is a layout diagram of an input/output gate circuit according to an example embodiment of the present disclosure;

FIG. 9 is a cross-sectional view taken along line II-II′ of FIG. 8;

FIG. 10 is a layout diagram of an input/output gate circuit according to an example embodiment of the present disclosure;

FIG. 11 is a circuit diagram of a memory device according to an example embodiment of the present disclosure;

FIG. 12 is a view illustrating an example of a memory bank of FIG. 11; and

FIG. 13 is a view illustrating an example of a memory cell structure included in a sub-cell block according to an example embodiment of the present disclosure.

### DETAILED DESCRIPTION

Hereinafter, example embodiments of the present disclosure will be described with reference to the accompanying drawings.

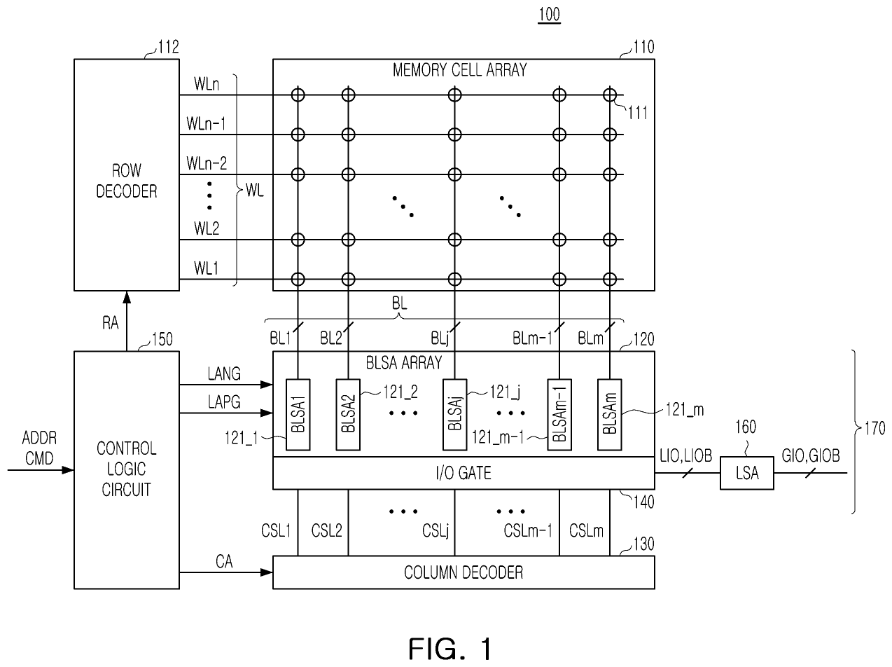

FIG. 1 is a block diagram illustrating a memory device according to an example embodiment of the present disclosure.

Referring to FIG. 1, a memory device 100 may be a storage device based on a semiconductor device. For example, the memory device 100 may be a volatile memory such as a dynamic random access memory (DRAM), a synchronous DRAM (SDRAM), a double data rate SDRAM (DDR SDRAM), a low power double data rate SDRAM (LPDDR SDRAM), a graphics double data rate SDRAM (GDDR SDRAM), DDR2 SDRAM, DDR3 SDRAM, DDR4 SDRAM, or Thyristor RAM, and a nonvolatile memory such as a phase change random access memory (PRAM), a magnetic random access memory (MRAM), or a resistive random access memory (RRAM).

The memory device 100 may include a memory cell array 110, a row decoder 112, a bit line sense amplifier (BLSA) 120, a column decoder 130, an input/output gate circuit 140, a control logic circuit 150, and a local sense amplifier (LSA) 160.

The memory cell array 110 may include a plurality of memory cells 111 disposed on a plurality of columns and a plurality of rows. In some example embodiments, the plurality of columns may be defined by a plurality of word lines WL1 to WLn (where n is a natural number), and the plurality of rows may be defined by a plurality of bit lines BL1 to BLm (where m is a natural number). The memory cell array 110 may include a plurality of memory banks.

The control logic circuit 150 may control an operation of the memory device 100. The control logic circuit 150 may receive a command CMD, an address ADDR, and data from a memory controller. The address ADDR may include a row address signal RA indicative of a row of the memory cell array 110 and a column address signal CA indicative of a column.

The control logic circuit 150 may generate various control signals required for an access operation, such as a read operation, a write operation, or a refresh operation, for the memory cell array 110 in response to the command CMD and the address ADDR. The control signal may include the row address signal RA, the column address signal CA, an N-type sense amplifier driving signal LANG, a P-type sense amplifier driving signal LAPG, and a column selection signal CSL. Additionally, the control signal may further include a repeater selection signal, and a memory block selection signal. The row address signal RA may be provided to the row decoder 112, and the column address signal CA and the column selection signal CSL may be provided to the column decoder 130.

The row decoder 112 may select a word line to be activated among the plurality of word lines WL1 to WLn of the memory cell array 110 based on the row address signal RA. To this end, the row decoder 112 may apply a driving voltage to a word line WLi (where i is a natural number less than or equal to n) corresponding to the row to be activated.

The column decoder 130 may select a bit line to be activated among the plurality of bit lines BL1 to BLm based on the column address CA. The column decoder 130 may select a column selection line CSLj (where j is a natural number less than or equal to m) to be activated among a plurality of column selection lines CSL1 to CSLm, and may select a bit line to be connected to the selected column selection line CSLj through the input/output gate circuit 140.

The bit line sense amplifier 120 may be connected to the bit lines BL1 to BLm of the memory cell array 110. The bit line sense amplifier 120 may include a plurality of bit line sense amplifiers 121_1, 121_2, . . . and 121_m connected to each bit line BL1 to BLm. The bit line sense amplifier 121_j (where j is a natural number less than or equal to m) may sense a voltage change of corresponding bit lines BLj, and may amplify the voltage change and output the amplified voltage. Data of the bit line BLj to be sensed and amplified by the bit line sense amplifier 120 may be selected through the input/output gate circuit 140.

Meanwhile, each of the plurality of bit lines BL1 to BLm may be a bit line pair including a bit line and a complementary bit line. The bit line pair may be implemented as a folded bit line sense amplifier type or an open bit line sense amplifier type, and the present disclosure is not limited thereto. In the case of the folded bit line sense amplifier type, two bit line sense amplifiers 120 may be disposed to face each other with respect to one memory block. In the case of the open bit line sense amplifier type, two memory blocks may be arranged to face each other with respect to one bit line sense amplifier 120.

The input/output gate circuit 140 may include a data latch for storing data read from the memory cell array 110 and a write driver for writing data to the memory cell array 110. The data read from the memory cell array 110 may be sensed by the bit line sense amplifier 120, and may be stored in the input/output gate circuit 140.

The column decoder 130 may control the input/output gate circuit 140 so as to activate the bit line sense amplifier 121_j (where j is a natural number less than or equal to m) corresponding to the selected column selection line CSLj. For example, the input/output gate circuit 140 may include column selection switches connected between one bit line BL and one local input/output line LIO and between one complementary bit line and one complementary local input/output line LIOB, and turned on in response to a column selection signal of the column selection line. As the bit line sense amplifier 121_j is activated, the input/output gate circuit 140 may transmit a potential output from the bit line sense amplifier 121_j to the local sense amplifier 160.

The local sense amplifier 160 may amplify a potential difference received from the bit line sense amplifier 120 through a local input/output line pair LIO and LIOB. The local sense amplifier 160 may output the amplified potential difference to an input/output buffer through a global input/output line pair GIO and GIOB. The local sense amplifier 160 may provide data stored in the memory cell array 110 to the input/output buffer through the global input/output line pair GIO and GIOB.

The bit line sense amplifier array 120, the input/output gate circuit 140 and the local sense amplifier 160 may be included in a sense amplifier circuit 170 for the memory cell array 110.

A plurality of column selection lines CSL1 to CSLm may be disposed to intersect a memory cell array region in which the memory cell array 110 is formed. For example, in order to reduce a load of the word line WL and the bit line BL, the memory cell array 110 may include sub-cell arrays, each having a plurality of word lines WL and a plurality of bit lines BL. The plurality of column selection lines may be disposed to intersect the sub-cell arrays so as to transmit a column selection signal to one of the plurality of sub-cell arrays.

The memory cell integration of the memory cell array region has increased due to the trend of miniaturization of semiconductor processes and demand for high-capacity memory devices. In a memory cell array region having a high degree of integration, it becomes increasingly difficult to integrate the column selection lines so that the column selection lines do not interfere with each other.

According to an example embodiment of the present disclosure, the input/output gate circuit 140 may include first and second column selection transistors connected in series between one bit line BL and a local input/output circuit LIO. The first column selection transistor may be turned on in response to a first column selection signal transmitted from a first column selection line extending in the same column direction as a direction in which the bit line extends. Additionally, the second column selection transistor may be turned on in response to a second column selection signal transmitted from a second column selection line extending in the same row direction as a direction in which the word line extends.

According to an example embodiment of the present disclosure, since the column selection lines may be disposed to intersect each other in a column direction and a row direction, the density of lines extending in the column direction may be reduced, and the flexibility of the arrangement of the column selection lines may be improved. For example, when the column address CA is a 6-bit address, 32 first column selection lines corresponding to the upper 5-bit address may extend in the column direction, and the second column selection lines corresponding to the lowest 1-bit address may extend in the row direction. As compared to a case in which 64 column selection lines extends in the column direction, the number of lines extending in the column direction may be reduced by half, and since some of the column selection lines may be disposed in the row direction, the flexibility of the arrangement may be improved.

The design complexity for arranging the column selection lines in the column direction and the row direction may not significantly increase. For example, the number of transistors per column selection switch included in the input/output gate circuit 140 may be increased from only one to two.

Accordingly, the column selection lines may be effectively disposed in a highly integrated memory cell array region, and the integration of the memory device may be improved.

Hereinafter, the structure of a sense amplifier circuit including a column selection switch according to an example embodiment of the present disclosure is described in detail.

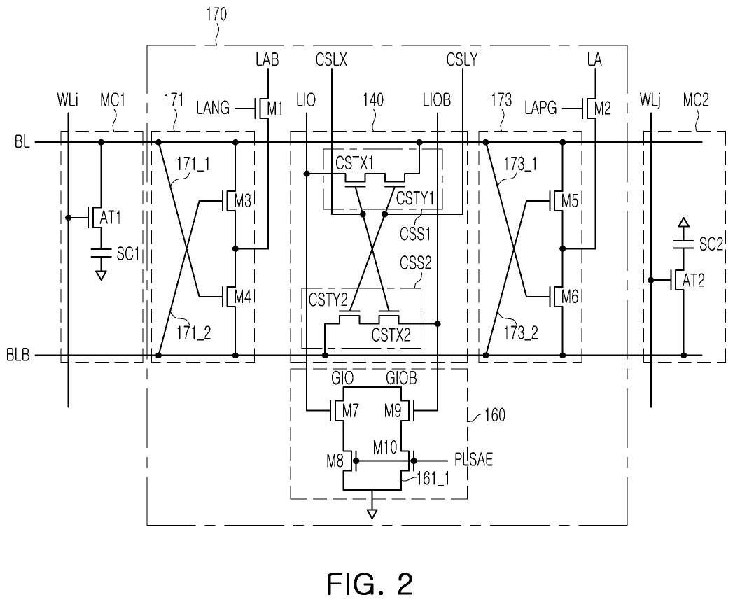

FIG. 2 is a circuit diagram illustrating a sense amplifier circuit according to an example embodiment of the present disclosure.

Referring to FIG. 2, a sense amplifier circuit 170 according to an example embodiment of the present disclosure may be connected to a bit line BL and a complementary bit line BLB. A plurality of memory cells may be connected to the bit line BL, and a plurality of word lines WL may be connected to each of the plurality of memory cells. Additionally, the plurality of memory cells may be connected to the complementary bit line BLB, and the plurality of word lines WL may be connected to each of the plurality of memory cells. In an example embodiment, the sense amplifier circuit 170 may be connected to one of the bit lines BL and the complementary bit line BLB.

In FIG. 2, one memory cell MC1 connected to a bit line BL, one word line WLi to the memory cell MC1, one memory cell MC2 connected to a complementary bit line BLB, and one word line WLj (with respect to the word lines j, is a natural number different than i, and less than or equal to n) connected to the memory cell MC2 are illustrated. Additionally, FIG. 2, illustrates that the memory cell MC1 includes a switching transistor AT1 and a capacitor SC1, and the memory cell MC2 includes a switching transistor AT2 and a capacitor SC2, but the structure of the memory cells MC1 and MC2 is not limited thereto.

The sense amplifier circuit 170 may include an N-type sense amplifier 171, a P-type sense amplifier 173, an input/output gate circuit 140, a local sense amplifier 160, and transistors M1 and M2. In some example embodiments, the transistors M1 to M10, CST1 and CST2 illustrated in FIG. 2 may be metal oxide semiconductor (MOS) transistors. In an example embodiment, the transistors M1, M3, M4, M7, M8, M9, M10, CST1 and CST2 may be N-channel transistors, for example, NMOS transistors. Additionally, the transistors M2, M5 and M6 may be P-channel transistors, for example, PMOS transistors. Each of the transistors M1 to M10, CST1 and CST2 may have sources, drains and gates as first input terminals, second input terminals and control terminals, respectively.

The N-type sense amplifier 171 may include a third transistor M3 and a fourth transistor M4. A gate of the third transistor M3 may be electrically connected to the complementary bit line BLB through a conductive line 171_2. A gate of the fourth transistor M4 may be electrically connected to the bit line BL through a conductive line 171_1. A source of the third transistor M3 and a source of the fourth transistor M4 may be electrically connected to the bit line BL and the complementary bit line BLB, respectively. A first voltage LAB may be input to a drain of the third transistor M3 and a drain of the fourth transistor M4 in response to an N-type sense amplifier driving signal LANG. The N-type sense amplifier driving signal LANG may have an active level (e.g., a high level) for turning on a first transistor M1 or an inactive level (e.g., a low level) for turning off the first transistor M1. The first voltage LAB may be a ground voltage.

The third transistor M3 and the fourth transistor M4 may be turned on or off according to the voltage change of the bit line BL or the complementary bit line BLB. When the third transistor M3 is turned on, the first voltage LAB may be provided to the bit line BL. When the fourth transistor M4 is turned on, the first voltage LAB may be provided to the complementary bit line BLB.

The P-type sense amplifier 173 may include a fifth transistor M5 and a sixth transistor M6. A gate of the fifth transistor M5 may be electrically connected to the complementary bit line BLB through a conductive line 173_2. A gate of the sixth transistor M6 may be electrically connected to the bit line BL through a conductive line 173_1. A source of the fifth transistor M5 and a source of the sixth transistor M6 may be electrically connected to the bit line BL and the complementary bit line BLB, respectively. A second voltage LA may be input to a drain of the fifth transistor M5 and a drain of the sixth transistor M6 in response to the P-type sense amplifier driving signal LAPG. The P-type sense amplifier driving signal LAPG may have an active level (e.g., a low level) for turning on a second transistor M2 or an inactive level (e.g., a high level) for turning off the second transistor M2. The second voltage LA may be a power supply voltage.

The fifth transistor M5 and the sixth transistor M6 may be turned on or off according to a voltage change of the bit line BL or the complementary bit line BLB. When the fifth transistor M5 is turned on, the second voltage LA may be provided to the bit line BL. When the sixth transistor M6 is turned on, the second voltage LA may be provided to the complementary bit line BLB.

The input/output gate circuit 140 may include a first column selection switch CSS1 and a second column selection switch CSS2. The first column selection switch CSS1 may be connected between the bit line BL and the local input/output line LIO, and the second column selection switch CSS2 may be connected between the complementary bit line BLB and the complementary local input/output line LIOB.

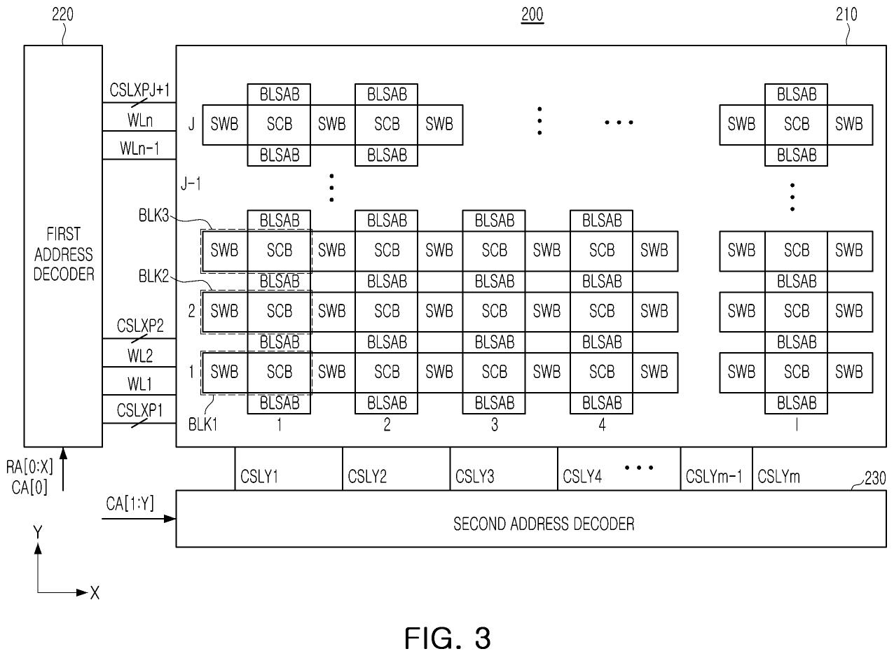

According to an example embodiment of the present disclosure, the first column selection switch CSS1 and the second column selection switch CSS2 may be turned on in response to the first column selection signal transmitted through a first column selection line CSLY extending in the column direction and a second column selection signal transmitted through a second column selection line CSLX extending in the row direction. The first column selection line CSLY extending in the column direction and the second column selection line CSLX extending in the row direction will be described later with reference to FIGS. 3 to 5.

The first column selection switch CSS1 may include a first column selection transistor CSTY1 and a second column selection transistor CSTX1 connected in series with each other. A drain of the first column selection transistor CSTY1 may be electrically connected to the bit line BL, a source of the first column selection transistor CSTY1 may be electrically connected to a drain of the second column selection transistor CSTX1, and a source of the second column selection transistor CSTX1 may be electrically connected to the local input/output line LIO. A gate of the first column selection transistor CSTY1 may be connected to the first column selection line CSLY, and a gate of the second column selection transistor CSTX1 may be connected to the second column selection line CSLX.

Additionally, the second column selection switch CSS2 may include a first column selection transistor CSTY2 and a second column selection transistor CSTX2 which are connected in series with each other. A drain of the first column selection transistor CSTY2 may be electrically connected to the complementary bit line BLB, and a source of the first column selection transistor CSTY2 may be electrically connected to a drain of the second column selection transistor CSTX2, and a source of the second column selection transistor CSTX2 may be electrically connected to the complementary local input/output line LIOB. A gate of the first column selection transistor CSTY2 may be connected to the first column selection line CSLY, and a gate of the second column selection transistor CSTX2 may be connected to the second column selection line CSLX.

A bit line pair BL and BLB to which the sense amplifier 170 is connected may be connected to the local input/output line pair LIO and LIOB through the column selection switches CSS1 and CSS2. The column selection switches CSS1 and CSS2 in the input/output gate circuit 140 may transmit potentials output from the N-type sense amplifier 171 and the P-type sense amplifier 173 to the local sense amplifier 160 in response to the column selection signal of the column selection line CSL, respectively.

The local sense amplifier 160 may include a seventh transistor M7, an eighth transistor M8, a ninth transistor M9, and a tenth transistor M10. The seventh transistor M7, the eighth transistor M8, the ninth transistor M9 and the tenth transistor M10 may be electrically connected in the local sense amplifier 160 through a conductive line 161_1.

A local enable signal PLSAE may be input to a gate of the eighth transistor M8 and a gate of the tenth transistor M10. The gate of the eighth transistor M8 and the tenth transistor M10 may be turned on through the local enable signal PLSAE, so that the local sense amplifier 160 may be activated. When the local sense amplifier 160 is activated, the seventh transistor M7 and the ninth transistor M9 may invert and output data of the local input/output line pair LIO and LIOB to the global input/output line pair GIO and GIOB, respectively.

The memory device 100 may operate as follows. First, when word lines WLi and WLj are activated, the switching transistor AT1 of the memory cell MC1 may be turned on so that charges may move between the bit line BL and the capacitor SC1 in the memory cell MC1, and the switching transistor AT2 of the memory cell MC2 may be turned on so that charges may move between the complementary bit line BLB and the capacitor SC2 in the memory cell MC2. Then, the N-type sense amplifier 171 or the P-type sense amplifier 173 amplifies a potential difference between the bit line BL and the complementary bit line BLB. Then, when the column selection signal is on an active level, the input/output gate circuit 140 may output data of the bit line BL or the complementary bit line BLB through the local input/output line LIO or the complementary local input/output line LIOB, respectively. For example, in response to the column selection signal, the column selection switches CSS1 and CSS2 in the input/output gate circuit 140 may transmit a potential output from the N-type sense amplifier 171 or the P-type sense amplifier 173 to the local sense amplifier 160. The local sense amplifier 160 may be activated by the local enable signal PLSAE to invert the data of the received local input/output line pair LIO and LIOB and output the data to the global input/output line pair GIO and GIOB.

In an example embodiment, the sense amplifier 170 may further include a precharge unit. The precharge unit may equalize voltages of the bit line BL and the complementary bit line BLB to precharge voltages before and after the operation of the N-type sense amplifier 171 or the P-type sense amplifier 173.

According to an example embodiment of the present disclosure, the first column selection lines CSLY extending in the column direction and the second column selection lines CSLX extending in the row direction may extend to intersect a memory cell array 210.

FIG. 3 is a block diagram illustrating a memory device according to an example embodiment of the present disclosure.

A memory device 200 of FIG. 3 may include a bank array 210, a first address decoder 220, and a second address decoder 230.

The bank array 210 may include I sub array blocks SCB in a first direction (X-direction) and J sub array blocks SCB in a second direction (Y-direction). In each of the sub array blocks SCB, a plurality of word lines WL extending in a first direction (X-direction), a plurality of bit lines BL extending in the second direction (Y-direction), and memory cells disposed at points in which the plurality of word lines WL and the plurality of bit lines BL intersect may be disposed. One memory block BLK0, BLK1 or BLK2 may include at least one sub array block.

I+1 sub-word line driver regions SWB may be disposed between the sub array blocks SCB disposed in the first direction (X-direction). In the sub-word line driver regions SWB, sub-word line drivers may be disposed.

J+1 bit-line sense amplifier regions BLSAB may be disposed between the sub array blocks SCB disposed in the second direction (Y-direction). A plurality of bit-line sense amplifiers may be disposed in the bit-line sense amplifier regions BLSAB.

The sub-word line driver regions SWB and the bit-line sense amplifier regions BLSAB in the bank array 210 may be disposed in a core circuit region in which core circuits for an operation of the memory device 200 are disposed. For example, a peripheral circuit region may be disposed on a peri substrate in a lower portion of the sub array block SCB.

The peri substrate may include a first address decoder 220 and a second address decoder 230 disposed in the peri circuit region around the core circuit region. The first address decoder 220 and the second address decoder 230 may perform operations of the row decoder 112 and the column decoder 130 described with reference to FIG. 1.

According to an example embodiment of the present disclosure, the first address decoder 220 may perform address decoding for selecting lines extending in the first direction (X-direction), and the second address decoder 230 may perform address decoding for selecting lines extending in the second direction (Y-direction).

According to an example embodiment of the present disclosure, first column address lines CSLY1 to CSLYm may extend in the second direction (Y-direction), and second column address line pairs CSLXP1 to CSLXPJ+1 may extend in the first direction (X-direction). One second column address line pair may be connected to I bit line sense amplifier regions BLSAB disposed in the first direction (X-direction), and may include a second reference column address line and a second complementary column address line.

The first address decoder 220 may receive a row address RA[0:X] and a first bit CA[0] of the column address from the control logic circuit. In an example embodiment, the partial bit CA[0] may be a least significant bit (LSB) of a column address CA[0:Y]. The control logic circuit may correspond to the control logic circuit 150 described with reference to FIG. 1.

The first address decoder 220 may select one of the word lines WL1 to WLn by decoding a row address RA[0:X], and may output a driving voltage to the selected word line. Additionally, the first address decoder 220 may output a second column selection signal to the second reference column address line or the second complementary column address line by decoding the address of the first bit CA[0].

In an example embodiment, the first address decoder 220 may select one of the second column address line pairs CSLXP1 to CSLXPJ+1 based on the row address RA[0:X]. For example, when a word line is selected based on a row address RA[0:X], it may be determined in which sub-cell array SCB the word line is included, and it may be determined which bit line sense amplifiers in which bit line sense amplifier region BLSAB may be activated.

The second address decoder 230 may select one of the first column selection lines CSLY1 to CSLYm by decoding remaining bits CA[1:X] except the first bit CA[0] of the column address, and may output a first column selection signal to the selected first column selection line.

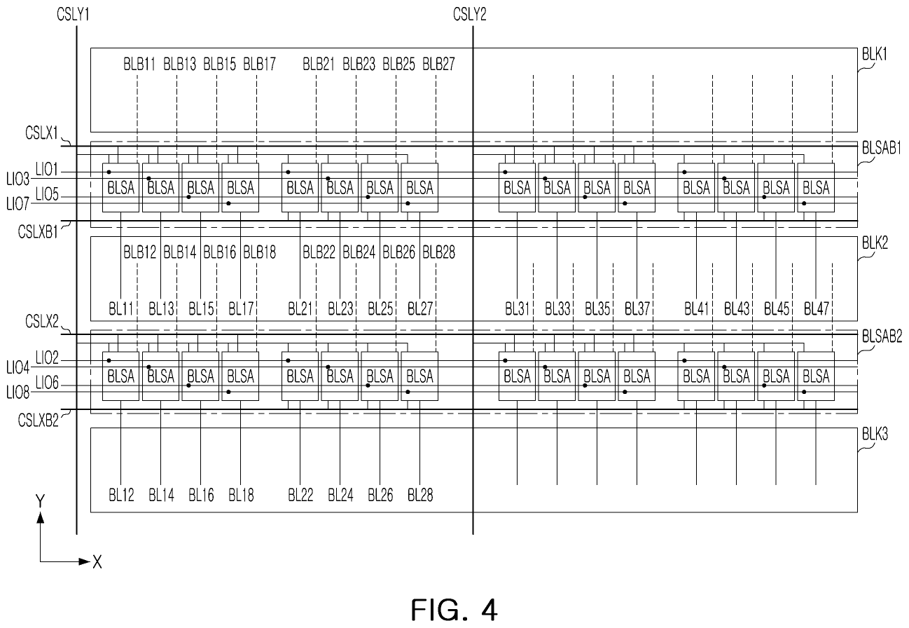

FIG. 4 is a view illustrating an arrangement structure of bit line sense amplifiers according to an example embodiment of the present disclosure.

FIG. 4 illustrates a plurality of memory blocks BLK1, BLK2 and BLK3, bit line sense amplifier regions BLSAB between the plurality of memory blocks, first column selection lines CSLY1 and CSLY2, second column selection lines CSLX1, CSLXB1, CSLX2 and CSLXB2, and a plurality of input/output lines LIO1 to LIO8, which may be included in the memory device 200 described with reference to FIG. 3.

Additionally, FIG. 4 illustrates a portion of a plurality of bit lines and a plurality of complementary bit lines that are necessary for explanation. In FIG. 4, a bit line BL is illustrated as a solid line, and a complementary bit line BLB is illustrated as a dotted line. A schematic pattern of the bit line and the complementary bit line in the drawing referenced in the following description does not denote an actual pattern of the bit line and the complementary bit line.

A plurality of bit line sense amplifiers BLSA may be disposed in the bit line sense amplifier regions BLSAB between the memory blocks BLK1, BLK2 and BLK3. Each of the plurality of bit line sense amplifiers BLSA may be connected to a corresponding bit line and a corresponding complementary bit line.

A plurality of local input/output lines LIO1 to LIO8 may extend to intersect the bit line sense amplifier regions BLSAB in the second direction (Y-direction). The plurality of local input/output lines LIO1 to LIO8 may be connected to input/output gate circuits 140 connected to the corresponding bit line sense amplifiers BLSA. In FIG. 4, the input/output gate circuit 140 is not illustrated, and a correspondence between the plurality of local input/output lines LIO1 to LIO8 and the bit line sense amplifiers BLSA is simply indicated by a dot pattern.

Based on a decoding result of the column address CA, the bit lines and the local input/output lines may be connected based on the first and second column selection signals transmitted from the first column selection lines CSLY1 and CSLY2 and the second column selection lines CSLX1, CSLXB1, CSLX2 and CSLXB2). In the example of FIG. 4, four bit lines and four local input/output lines may be connected based on one column address CA. The bit lines connected to the local input/output lines based on one column address CA may be referred to as a bit line group.

The plurality of first column selection lines CSLY1 and CSLY2 may extend in the same second direction (Y-direction) as the bit lines across the memory blocks BLK1, BLK2 and BLK3. Each of the plurality of second column selection lines CSLX1, CSLXB1, CSLX2 and CSLXB2 may extend in the same first direction (X-direction) as the word lines across the bit line sense amplifier region BLSAB.

According to an example embodiment of the present disclosure, the bit line groups may be selected in response to the first column selection signal transmitted from the first column selection line and the second column selection signal transmitted from the second column selection line.

For example, FIG. 4 illustrates first column selection lines CSLY1 and CSLY2 extending across the plurality of memory blocks BLK1, BLK2 and BLK3. In one memory cell block group, one first column selection line may select two bit line groups. Additionally, in the one memory cell block group, one second column selection line pair may select one of the two bit line groups.

For example, the first column selection line CSLY1 may select a first bit line group (BL11, BL13, BL15 and BL17) and a second bit line group (BL21, BL23, BL25 and BL27) among the bit lines associated with a first bit line sense amplifier region BLSAB1. Additionally, the first column selection line CSLY2 may select a third bit line group (BL31, BL33, BL35 and BL37) and fourth bit line group (BL41, BL43, BL45 and BL47) among the bit lines associated with the first bit line sense amplifier region BLSAB1.

The second column selection line pair CSLX1 and CSLXB1 may select one of the two bit line groups in a state in which the two bit line groups are selected. For example, when the second reference column selection line CSLX1 is activated based on one bit of the column address CA, the first bit line group (BL11, BL13, BL15 and BL17) and the third bit line group (BL31, BL33, BL35 and BL37) of the first bit line sense amplifier region BLSAB1 may be selected. Additionally, based on the one bit, when the second complementary column selection line CSLXB1 is activated, the second bit line group (BL21, BL23, BL25 and BL27) and the fourth bit line group (BL41, BL43, BL45 and BL47) of the first bit line sense amplifier region BLSAB1 may be selected.

When the first column selection line CSLY1 and the second reference column selection line CSLX1 are activated simultaneously, the first bit line group (BL11, BL13, BL15 and BL17) is selected, and the first bit line group (BL11, BL13, BL15 and BL17) may be connected to a plurality of local input/output lines LIO1, LIO3, LIO5 and LIO7. When the first column selection line CSLY1 and the second complementary column selection line CSLXB1 are activated simultaneously, the second bit line group (BL21, BL23, BL25 and BL27) are selected, and the second bit line group (BL21, BL23, BL25 and BL27) may be connected to the plurality of local input/output lines LIO1, LIO3, LIO5 and LIO7.

Although the complementary local input/output lines are not illustrated in FIG. 4, the column selection signals transmitted through the first column selection line and the second column selection line may connect the complementary bit lines to the complementary local input/output lines. For example, when the first column selection line CSLY1 and the second reference column selection line CSLX1 are activated simultaneously, a first complementary bit line group (BLB11, BLB13, BLB15 and BLB17) are selected together with the first bit line group (BL11, BL13, BL15 and BL17), and the first complementary bit line group (BLB11, BLB13, BLB15 and BLB17) may be connected to a plurality of complementary local input/output lines.

In an example embodiment, when there is a defect in a memory cell, or the like, the bit line group including the bit line connected to the defective memory cell may be a spare bit line group. For example, when the first bit line group is replaced with the spare bit line group, a column address for selecting the first column selection line CSLY1 and the second reference column selection line CSLX1 may be decoded to select a first spare column selection line and the second reference column selection line CSLX1. However, when the second bit line group is not replaced, a column address for selecting the first column selection line CSLY1 and a second complementary column selection line CSLX1 may be decoded without any change to select the first column selection line CSLY1 and the second complementary column selection line CSLX1. In this case, the second address decoder 230 as described with reference to FIG. 3 may further refer to a least significant bit CA[0] of the column address for address decoding.

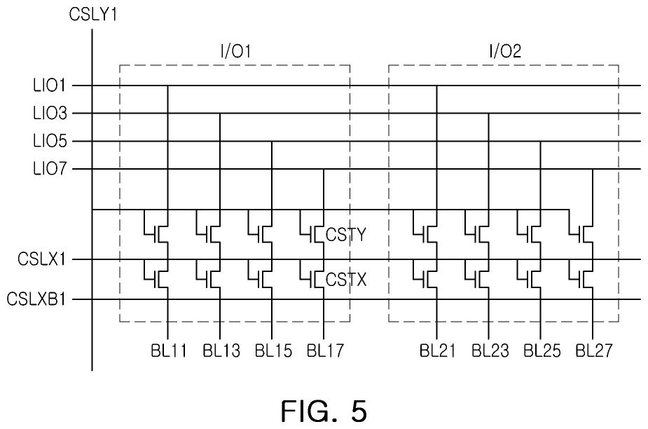

FIG. 5 is a view illustrating a connection structure of bit lines and local input/output lines according to an example embodiment of the present disclosure.

FIG. 5 illustrates a first input/output gate I/O1, a second input/output gate I/O2, a first bit line group (BL11, BL13, BL15 and BL17), a second bit line group (BL21, BL23, BL25 and BL27), a first column selection line CSLY1, a second column selection line pair CSLX1 and CSLXB1, and a plurality of local input/output lines LIO1, LIO3, LIO5 and LIO7.

The first input/output gate I/O1 may include column selection transistors for connecting the first bit line group (BL11, BL13, BL15 and BL17) to the plurality of local input/output lines LIO1, LIO3, LIO5 and LIO7, and the second input/output gate I/O2 may include column selection transistors for connecting the second bit line group (BL21, BL23, BL25 and BL27) to the plurality of local input/output lines LIO1, LIO3, LIO5 and LIO7.

A first column selection transistor CSTY and a second column selection transistor CSTX may be connected in series between one bit line and one local input/output line. In the example of FIG. 5, a drain of the first column selection transistor CSTY may be connected to a local input/output line, and a source of the first column selection transistor CSTY may be connected to a drain of the second column selection transistor CSTX, and a source of the second column selection transistor CSTX may be connected to the bit line. However, the present disclosure is not limited thereto, and the drain of the second column selection transistor CSTX may be connected to a local input/output line, the source of the second column selection transistor CSTX may be connected to a drain of the first column selection transistor CSTY, and the source of the first column selection transistor CSTY may be connected to the bit line.

Gates of the first column selection transistors CSTY corresponding to the first and second bit line groups (BL11 to BL27) may be connected to the first column selection line CSLY1. Additionally, gates of the second column selection transistors CSTX corresponding to the first bit line group (BL11, BL13, BL15 and BL17) may be connected to the second reference column selection line CSTX1, and gates of the second column selection transistors CSTX corresponding to the second bit line group (BL21, BL23, BL25 and BL27) may be connected to a second complementary column selection line CSTXB1.

According to an example embodiment of the present disclosure, since the number of the first column selection lines extending in the column direction may be reduced by half, the column selection lines may be effectively disposed in the memory cell array region.

However, the sum of the first column selection lines and the second column selection lines may not necessarily be reduced. For example, when one column selection transistor is used per bit line, 2⁶=64 second direction (Y-direction) column selection lines may be required when the column address CA is a 6-bit address. According to an example embodiment of the present disclosure, 32 first column selection lines and 2 second column selection lines may be required for the bit line sense amplifier regions arranged in the first direction (X-direction). However, when there are 16 bit line sense amplifier regions arranged in the second direction (Y-direction), 32 first column selection lines and 2×16=32 second column selection lines may be required. However, when the density of interconnection lines extending in the second direction (Y-direction) is high, the number of column selection lines extending in the second direction (Y-direction) may be reduced by half, and the column selection lines extending in the first direction (X-direction) may be added, so that the column selection lines may be effectively disposed.

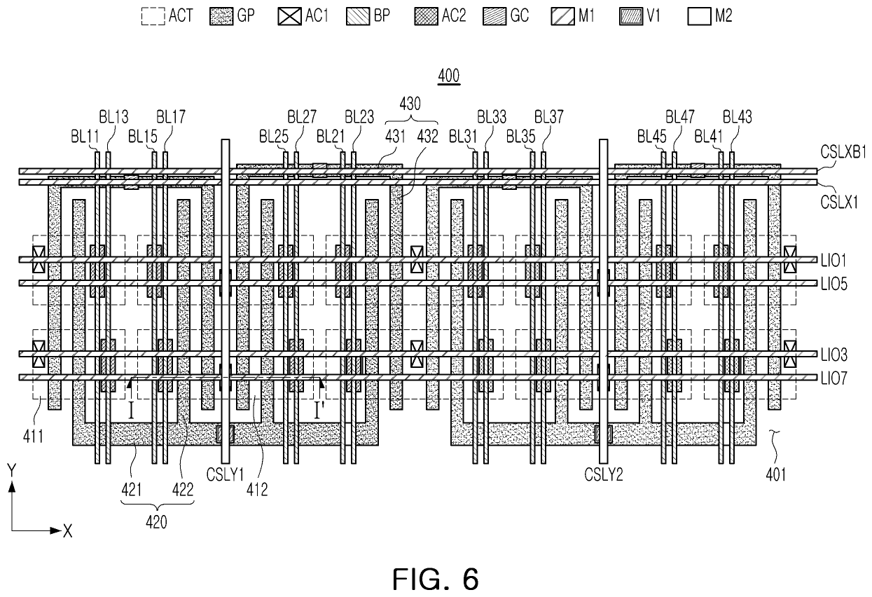

Hereinafter, with reference to FIGS. 6 to 10, an arrangement of the input/output gate circuit according to an example embodiment of the present disclosure will be described in detail.

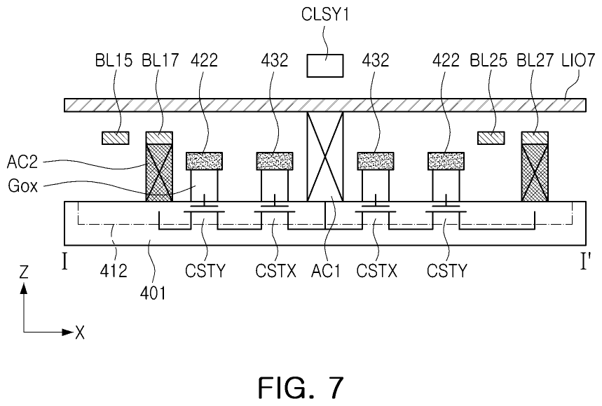

FIG. 6 is an arrangement diagram of an input/output gate circuit according to an example embodiment of the present disclosure. FIG. 7 is a cross-sectional view taken along line I-I′ of FIG. 6.

FIG. 6 and FIG. 7 illustrate an active region ACT, a gate pattern GP, a first active contact AC1, a bit line pattern BP, a second active contact AC2, a gate contact GC, a first metal interconnection line M1, a via V1, and a second metal interconnection line M2. The first active contact AC1 may connect the active region ACT and the first metal interconnection line M1, the second active contact AC2 may connect the active region ACT and the bit line pattern BP, and the via V1 may connect the first metal interconnection line M1 and the second metal interconnection line M2.

Referring to FIG. 6, an input/output gate circuit 400 may include a plurality of active regions 411 and 412, a first gate structure 420, a second gate structure 430, a plurality of bit lines BL11 to BL47, a plurality of local input/output lines LIO1, LIO3, LIO5 and LIO7, a plurality of first column selection lines CSLY1 and CSLY2, and a plurality of second column selection lines CSLX1 and CSLXB1.

The plurality of active regions 411 and 412 may be arranged in the first direction (X-direction) and the second direction (Y-direction), parallel to an upper surface of a substrate 401. Specifically, the second active regions 412, each of which provides column selection transistors for two bit lines, may be arranged in the first direction (X-direction) and the second direction (Y-direction). Additionally, the first active regions 411 providing column selection transistors for one bit line in positions spaced apart from the second active regions 412 in the first direction (X-direction) may be arranged in the second direction (Y-direction). In an example embodiment, a length of the active regions 411 and 412 in the first direction (X-direction) may be longer than a length of the active regions 411 and 412 in the second direction (Y-direction).

First gate structures 420 included in the first column selection transistor and second gate structures 430 included in the second column selection transistor may be formed on an upper surface of the substrate 401. The first gate structure 420 may include a first main pattern 421 spaced apart from the active regions 411 and 412 in the second direction (Y-direction) and extending in the first direction (X-direction), and a plurality of first finger patterns 422 extending from the first main pattern 421 in the second direction (Y-direction) and spaced apart from each other in the first direction (X-direction) by intersecting the active regions arranged in the second direction (Y-direction).

The second gate structure 430 may include a second main pattern 431 spaced apart in an opposite direction from the first main pattern 421 based on the active regions 411 and 412 and extending in the first direction (X-direction), and a plurality of second finger patterns 432 extending in the second direction (Y-direction) from the second main pattern 431 and spaced apart from each other in the first direction (X-direction) by intersecting the active regions arranged in the second direction (Y-direction).

On upper surface of the active regions 411 and 412, the first finger pattern 422 and the second finger pattern 432 may be disposed adjacently to each other in the first direction (X-direction). A first active contact AC1 may be formed in the middle of the second active region 412 to connect the second active region 412 to the local input/output line, and a second active contact AC2 may be formed at an edge of the second active region 412 in the first direction (X-direction) to connect the second active region 412 to the bit line. Additionally, the first active contact AC1 may be formed at one edge of the first direction (X-direction) of the first active region 411, and a second active contact AC2 may be formed at an opposite edge thereof. One first finger pattern 422 and one second finger pattern 432 may be disposed between the first active contact AC1 and the second active contact AC2.

In an embodiment, two second gate structures 430 may be disposed to surround the first finger patterns 422 of one first gate structure 420. In the example of FIG. 6, the first gate structure 420 may have a fork shape having four first finger patterns 422, and the second gate structure 430 may have a U shape having two second finger patterns 432. However, the present disclosure is not limited thereto, and the number of finger patterns 422 and 432 may vary depending on the number of bit lines included in a bit line group that may be selected by one column address.

The plurality of bit lines BL11 to BL47 may extend to intersect the plurality of active regions arranged in the second direction (Y-direction), and may be arranged in the first direction (X-direction). The plurality of bit lines BL11 to BL47 may be connected to the active regions 411 and 412 via the second active contact AC2.

The plurality of input/output lines LIO1, LIO3, LIO5 and LIO7 extend to intersect the plurality of active regions arranged in the first direction (X-direction), and may be spaced apart from each other in the second direction (Y-direction). The plurality of input/output lines LIO1, LIO3, LIO5 and LIO7 may be connected to the active regions 411 and 412 via the first active contact AC1.

The first finger pattern 422 and the second finger pattern 432 adjacent to each other in the first direction (X-direction), and the active regions adjacent to the first finger pattern 422 and the second finger pattern 432 in the first direction (X-direction) may provide a first column selection transistor and a second column selection transistor connected in series with each other.

Referring to FIG. 7, an active region 412 may be formed inside the substrate 401. The active region may include source/drain regions formed around the gate structure and a channel region formed in a lower portion of the gate structure. The gate structure may include a finger pattern and a gate insulating layer Gox formed in a lower portion of the finger pattern. The first finger pattern 422 may be included in a first column selection transistor CSTY, and the second finger pattern 432 may be included in a second column selection transistor CSTX.

The first and second finger patterns 422 and 432 adjacent to each other may be connected to each other in series by sharing the source/drain region. The source/drain region formed on an opposite side of the second finger pattern 432 based on the first finger pattern 422 may be connected to the bit lines BL17 and BL27 through the second active contact AC2. The source/drain region formed on an opposite side of the first finger pattern 422 based on the second finger pattern 432 may be connected to the local input/output line LIO7 through the first active contact AC1.

Referring again to FIG. 6, the plurality of input/output lines LIO1, LIO3, LIO5 and LIO7 may be selectively connected to the first bit line group (BL11, BL13, BL15 AND BL17), the second bit line group (BL21, BL23, BL25 AND BL27), the third bit line group (BL31, BL33, BL35 and BL37), or the fourth bit line group (BL41, BL43, BL45 AND BL47) through the first and second column selection transistors.

The first gate structures 420 may be connected to the first column selection lines CSLY1 and CSLY2 extending in the second direction (Y-direction), and the second gate structures 430 may be connected to the second column selection lines CSLX1 and CSLXB1 extending in the first direction (X-direction). For example, the second main patterns 431 may be connected to the second column selection lines CSLX1 and CSLXB1 through the gate contact GC. Additionally, the first main patterns 421 may be connected to the first column selection lines CSLY1 and CSLY2 through the gate contact GC, the first metal pattern M1 and the via pattern V1. In FIG. 6, the gate contact GC and the first metal pattern M1 in a lower portion of the via pattern V1 are not illustrated.

When the first gate structure 420 has four first finger patterns 422, and each of the first finger patterns 422 intersect two active regions, the first gate structure 420 may provide eight first column selection transistors. When the second gate structure 430 has two second finger patterns 432, and each of the second finger patterns 432 intersects two active regions, the second gate structure 430 may provide four second column selection transistors.

When a column select signal provided by one first column selection line is activated, eight first column selection transistors may be turned on, and when the second main column selection line or the second complementary column selection line is complementarily activated, four of the eight second column selection transistors connected to the eight first column selection transistors may be turned on.

In an example embodiment, the local input/output lines LIO1, LIO3, LIO5 and LIO7 and the second column selection lines CSLX1 and CSLXB1 may be disposed on a metal layer on the same level. The bit lines BL11 to BL47 may be disposed on a metal layer on a level lower than a level of the local input/output lines LIO1, LIO3, LIO5 and LIO7 and the second column selection lines CSLX1 and CSLXB1. Additionally, the first column selection lines CSLY1 and CSLY2 may be disposed on a metal layer on a level higher than a level of the local input/output lines LIO1, LIO3, LIO5 and LIO7 and the second column selection lines CSLX1 and CSLXB1.

A layout of the input/output gate according to an example embodiment of the present disclosure is not limited to that described with reference to FIGS. 6 and 7. In order to reduce the density of the first and second column selection transistors, an arrangement direction of the first and second column selection transistors may be different from that described with reference to FIGS. 6 and 7.

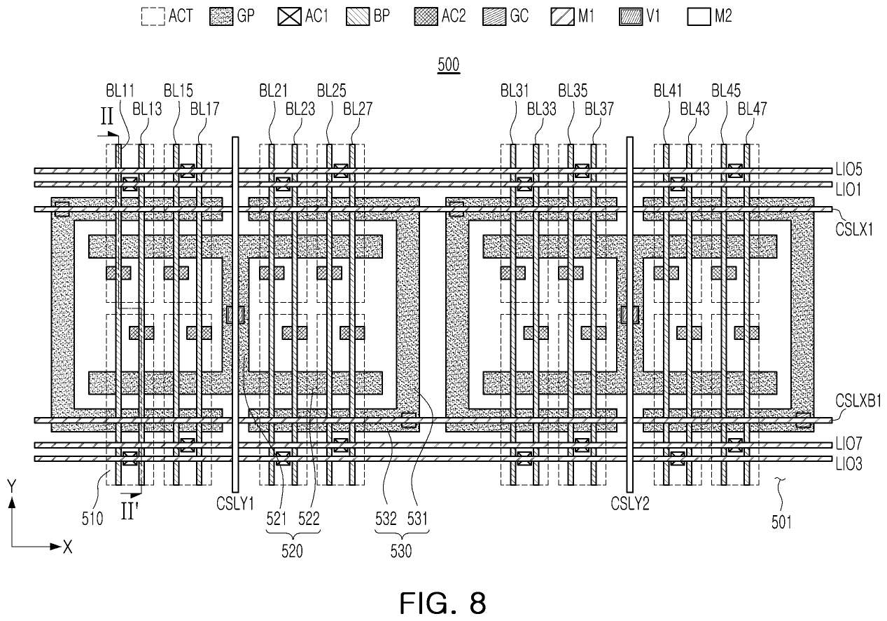

Hereinafter, the layout of the input/output gate circuit according to an example embodiment of the present disclosure is described with reference to FIGS. 8 to 10.

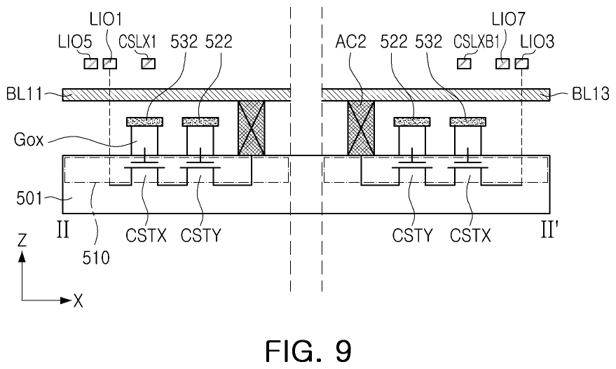

FIG. 8 is a layout diagram of an input/output gate circuit according to an example embodiment of the present disclosure. FIG. 9 is a cross-sectional view taken along line II-II′ of FIG. 8.

FIGS. 8 and 9 illustrate an active region ACT, a gate pattern GP, a first active contact AC1, a bit line pattern BP, a second active contact AC2, a gate contact GC, a first metal interconnection line M1, a via V1, and a second metal interconnection line M2. The first active contact AC1 may connect the active region ACT and the first metal interconnection line M1, the second active contact AC2 may connect the active region ACT and the bit line pattern BP, and the via V1 may connect the first metal interconnection line M1 and the second metal interconnection line M2.

Referring to FIG. 8, an input/output gate circuit 500 may include a plurality of active regions 510, a first gate structure 520, a second gate structure 530, a plurality of bit lines BL11 to BL47, a plurality of local input/output lines LIO1, LIO3, LIO5 and LIO7, a plurality of first column selection lines CSLY1 and CSLY2 and a plurality of second column selection lines CSLX1 and CSLXB1.

A plurality of active regions 511 and 512 may be arranged in the first direction (X-direction) and the second direction (Y-direction), parallel to an upper surface of a substrate 501. The active regions 510 providing column selection transistors for two bit lines may be arranged in the first direction (X-direction) and the second direction (Y-direction). In an example embodiment, a length of the active regions 510 in the second direction (Y-direction) may be longer than a length of the active regions 510 in the first direction (X-direction).

First gate structures 520 included in the first column selection transistor and second gate structures 530 included in the second column selection transistor may be formed on the upper surface of the substrate 501. The first gate structure 520 may include a first main pattern 521 extending in the second direction (Y-direction) between the active regions 510, and a plurality of branch patterns 522 extending in the first direction (X-direction) from the first main pattern 521 and intersecting the active regions arranged in the first direction (X-direction).

The second gate structure 530 may include a second main pattern 531 extending in the second direction (Y-direction) between or around the active regions 510, and a plurality of finger patterns 532 extending in the first direction (X-direction) from the second main pattern 531 and respectively disposed adjacently to one branch pattern by intersecting the active regions arranged in the second direction (Y-direction).

In an example embodiment, the first gate structure 520 may include first branch patterns extending toward a first side based on the first main pattern 521, and two first branch patterns extending toward a second side opposite to the first side. In the example of FIG. 8, the first gate structure 520 may be formed in an H shape.

In an example embodiment, two second gate structures 530 may be disposed in a form to surround one first gate structure 520. One second gate structure may surround the first branch patterns extending toward the first side, and the other second gate structure may surround the first branch patterns extending toward the second side. In the example of FIG. 8, each of the two second gate structures 530 may have a U-shape including two finger patterns.

The plurality of bit lines BL11 to BL47 may extend to intersect the plurality of active regions arranged in the second direction (Y-direction), and may be arranged in the first direction (X-direction). The plurality of bit lines BL11 to BL47 may be connected to the active regions 510 via the second active contact AC2.

The plurality of input/output lines LIO1, LIO3, LIO5 and LIO7 may extend to intersect the plurality of active regions arranged in the first direction (X-direction), and may be spaced apart from each other in the second direction (Y-direction). The plurality of input/output lines LIO1, LIO3, LIO5 and LIO7 may be connected to the active regions 510 via the first active contact AC1.

The branch pattern 522 and the finger pattern 532 adjacent to each other in the second direction (Y-direction), and the active regions adjacent to the branch pattern 522 and the finger pattern 532 in the second direction (Y-direction) may provide a first column selection transistor and a second column selection transistor connected to each other in series.

Referring to FIG. 9, an active region 510 may be formed in the substrate 501. The active region may include source/drain regions formed around the gate structure and a channel region formed in a lower portion of the gate structure. The gate structure may include a finger pattern and a gate insulating layer Gox, or may include a branch pattern and a gate insulating layer Gox. The branch pattern 522 may be included in a first column selection transistor CSTY, and the finger pattern 532 may be included in a second column selection transistor CSTX.

The adjacent branch patterns 522 and finger patterns 532 may be connected in series by sharing a source/drain region. A source/drain region formed on an opposite side of the finger pattern 532 based on the branch pattern 522 may be connected to the bit line BL13 through the second active contact AC2. A source/drain region formed on an opposite side of the branch pattern 522 based on the finger pattern 532 may be connected to the local input/output line through the first active contact AC1.

Referring again to FIG. 8, the plurality of input/output lines LIO1, LIO3, LIO5 and LIO7 may be selectively connected to the first bit line group (BL11, BL13, BL15 and BL17), the second bit line group (BL21, BL23, BL25 and BL27), the third bit line group (BL31, BL33, BL35 and BL37), or the fourth bit line group (BL41, BL43, BL45 and BL47) through the first and second column selection transistors, The first gate structures 520 may be connected to the first column selection lines CSLY1 and CSLY2 extending in the second direction (Y-direction) through the gate contact GC, the first metal pattern M1, and the via pattern V1 stacked in upper portions of the first main patterns 521. The second gate structures 530 may be connected to the second column selection lines CSLX1 and CSLXB1 through the gate contact GC disposed on upper portions of the second main patterns 531.

When the first gate structure 520 has four branch patterns 522, and each of the branch patterns 522 crosses two active regions, the first gate structure 520 may provide eight first column selection transistors. When the second gate structure 430 has two second finger patterns 432, and each of the second finger patterns 432 intersect two active regions, the second gate structure 430 may provide four second column selection transistors.

In an example embodiment, the local input/output lines LIO1, LIO3, LIO5 and LIO7 and the second column selection lines CSLX1 and CSLXB1 may be disposed in a metal layer on the same level. The bit lines BL11 to BL47 may be disposed in a metal layer on a level lower than a level of the local input/output lines LIO1, LIO3, LIO5 and LIO7 and the second column selection lines CSLX1 and CSLXB1. Additionally, the first column selection lines CSLY1 and CSLY2 may be disposed on a metal layer on a level higher than a level of the local input/output lines LIO1, LIO3, LIO5 and LIO7 and the second column selection lines CSLX1 and CSLXB1.

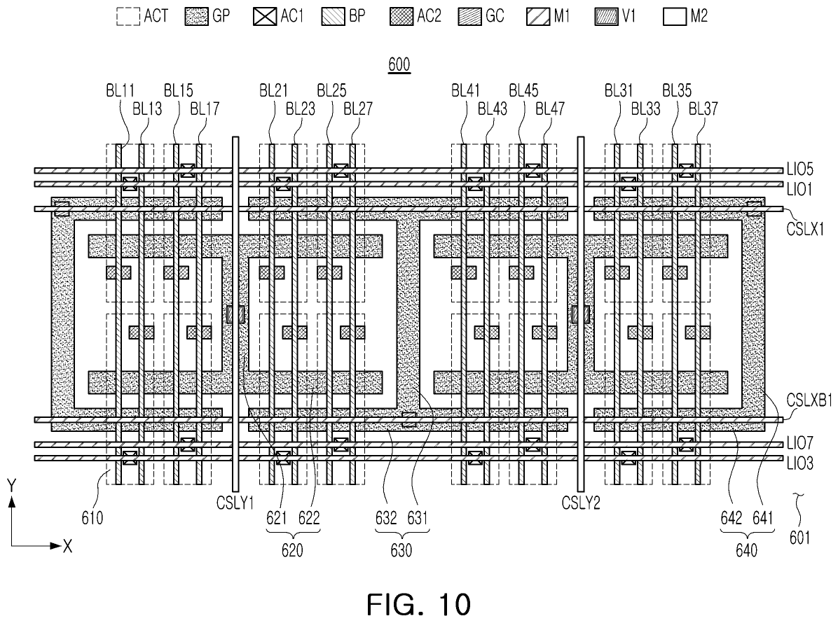

FIG. 10 is a layout diagram of an input/output gate circuit according to an example embodiment of the present disclosure.

An input/output gate circuit 600 of FIG. 10 may have a layout, similar to the input/output gate circuit 500 described with reference to FIG. 8. Hereinafter, a layout of FIG. 10 will be described in detail focusing on differences from the layout of FIG. 8.

In the example of FIG. 10, first gate structures 620 may include a first main pattern 621 extending in the second direction (Y-direction) between active regions 610, and a plurality of first branch patterns 622 extending from the first main pattern 621 and intersecting the active regions arranged in the first direction (X-direction).

Additionally, a plurality of second gate structures may be disposed to surround the first gate structures 620. The second gate structures may include full gate structures 630 and half gate structures 640.

The full gate structures 630 may have a shape, similar to the first gate structures 620. The full gate structures 630 may include a second main pattern 631 extending in the second direction (Y-direction) between two first gate structures 620 adjacent to each other in a first direction (X-direction), and a plurality of second branch patterns 632 extending from the second main pattern 631 and intersecting the active regions arranged in the first direction (X-direction). The full gate structures 630 may be shaped to surround the first branch patterns in a facing direction, in the two first gate structures 620 adjacent to each other.

The half gate structures 640 may have a shape, similar to the second gate structures 530 described with reference to FIG. 8. The half gate structures 640 may include a third main pattern 641 adjacent to the first gate structure 620 in the first direction (X-direction) and extending in the second direction (Y-direction), and finger patterns 642 extending from the third main pattern 641 and formed to surround the first branch patterns in the facing direction, in the adjacent first gate structure.

Comparing FIG. 8 and FIG. 10, unlike the two second gate structures 530 disposed between the two first gate structures in FIG. 8, the gate structures may be combined into one full gate structure in FIG. 10. One full gate structure may have a shape in which the two second gate structures 530 share a main pattern. The two second gate structures may have two main patterns, but since one full gate structure has one main pattern, a width of the input/output gate circuit 600 in the first direction may be reduced.

However, although the shapes in which the bit lines are arranged in FIGS. 8 and 10 are similar to each other, the orders of the bit lines may be different. For example, the second gate structures arranged in the first direction (X-direction) in FIG. 8 may be alternately connected to the second reference column selection line and the second complementary column selection line. That is, different second column selection lines may be connected to two adjacent second gate structures. On the other hand, one second column selection line may be connected to the full gate structures corresponding to the two adjacent second gate structures in FIG. 10. For example, the column selection signals applied to the branch patterns extending in a direction in which the branch patterns face each other in the two adjacent first gate structures in FIGS. 8 and 10 may be different from each other.

According to an example embodiment of the present disclosure, the flexibility of an interconnection design of a memory device may be improved. Specifically, since column selection lines extending to intersect a memory cell array may be disposed in the column direction and the row direction, the density of lines extending in the column direction may be reduced.

The present disclosure may also be applied to a case in which the memory cell array circuit and the peripheral circuit of the memory device are stacked on different semiconductor layers, and in this case, lowering the density of lines extending in the column direction may improve the integration of the memory device.

Hereinafter, the structure of a memory device to which an input/output gate circuit according to an example embodiment of the present disclosure may be applied is described in detail.

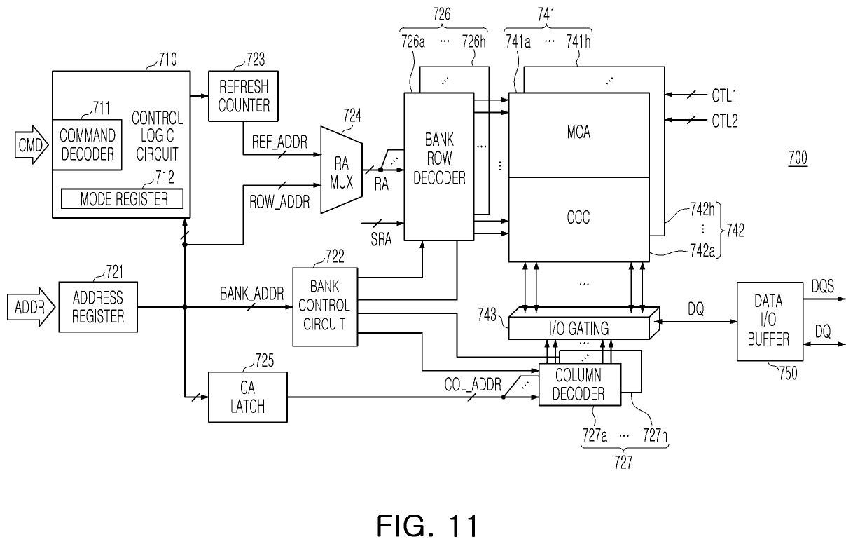

FIG. 11 is a circuit diagram of a memory device according to an example embodiment of the present disclosure.

Referring to FIG. 11, a memory device 700 may include a control logic circuit 710, an address register 721, a bank control circuit 722, a refresh counter 723, a row address multiplexer 724, a column address latch 725, a row decoder 726, a column decoder 727, a memory core circuit 741, a sense amplifier 742, an input/output gate circuit 743, and a data input/output buffer 750.

The memory device 700 may include a first semiconductor layer and a second semiconductor layer disposed in a vertical direction, perpendicular to the substrate. The memory core circuit 741 may be formed in a cell region of the first semiconductor layer and a core circuit region of the second semiconductor layer. The address register 721, the bank control circuit 722, the refresh counter 723, the row address multiplexer 724, the column address latch 725, the row decoder 726, the column decoder 727, the sense amplifier 742, the input/output gate circuit 743 and the data input/output buffer 750 may be included in a peripheral circuit region of the second semiconductor layer.

The memory core circuit 741 may include a plurality of memory core circuits 741a to 741h. Additionally, a plurality of row decoders 726 (726a to 726h), a plurality of column decoders 727 (727a to 727h) and a plurality of sense amplifiers 742 (742a to 742h) may be connected to the plurality of memory core circuits 741a to 741h, respectively.

Each of the plurality of memory core circuits 741a to 741h, the plurality of sense amplifiers 742a to 742h, the plurality of column decoders 727a to 727h, and the plurality of row decoders 726a to 726h may be included in a plurality of banks.

Each of the plurality of memory core circuits 741a to 741h may include a memory cell array MCA and a core control circuit CCC. The memory cell array MCA may be disposed in the first semiconductor layer, and the core control circuit CCC may overlap the memory cell array MCA in a direction, parallel to an upper surface of the substrate in the second semiconductor layer.

The memory cell array MCA may include a plurality of word lines, a plurality of bit lines, and a plurality of memory cells connected to the plurality of word lines and the plurality of bit lines.

According to an example embodiment of the present disclosure, the plurality of bit lines may be hierarchized into local bit lines and global bit lines. The memory cell array MCA may include one or more memory cell structures having a plurality of cell capacitors and a plurality of cell transistors disposed on each of a plurality of levels defined in a vertical direction, perpendicular to the substrate.

The cell transistors disposed on one or more of the plurality of levels may be used as selection transistors and precharge transistors. One selection transistor and one precharge transistor may be electrically connected to one local bit line. For example, a first impurity region of the selection transistor may be connected to the local bit line, and a second impurity region may be connected to the global bit line. Additionally, a first impurity region of the precharge transistor may be connected to the local bit line, and the second impurity region may be connected to the precharge line.

The core control circuit CCC may include circuits for controlling the memory cell array MCA. For example, the core control circuit CCC may include a sub-word line driver circuit for driving the plurality of word lines, and a bit line sense amplifier circuit for sensing voltage changes of the plurality of bit lines and amplifying the voltage changes.

According to an example embodiment of the present disclosure, the core control circuit CCC may overlap the memory cell array MCA in the vertical direction, perpendicular to the substrate. For example, the bit line sense amplifier circuit may be connected to the global bit line in an upper portion of the memory cell structure, and may be selectively connected to one local bit line depending on whether the selection transistors connected to the global bit line are turned on.

The address register 721 may receive an address ADDR including a bank address BANK_ADDR, a row address ROW_ADDR, and a column address COL_ADDR from a memory controller connected to the memory device 700. The address register 721 may provide the received bank address BANK_ADDR to the bank control circuit 722, may provide the received row address ROW_ADDR to the row address multiplexer 724, and may provide the received column address COL_ADDR to the column address latch 725.

The bank control circuit 722 may generate bank control signals in response to the bank address BANK_ADDR. In response to the bank control signals, a row decoder corresponding to the bank address BANK_ADDR, among the plurality of row decoders 724a to 724h, may be activated, and a column decoder corresponding to the bank address BANK_ADDR, among the plurality of column decoders 727a to 727h, may be activated.

The row address multiplexer 724 may receive the row address ROW_ADDR from the address register 721, and may receive a refresh row address REF_ADDR from the refresh counter 723. The row address multiplexer 724 may selectively output the row address ROW_ADDR or the refresh row address REF_ADDR as a row address RA. The row address RA output from the row address multiplexer 724 may be applied to each of the plurality of row decoders 726a to 726h.

The refresh counter 723 may sequentially increase or decrease the refresh row address REF_ADDR according to the control of the control logic circuit 710.

A row decoder activated by the bank control circuit 722, among the plurality of row decoders 726a to 726h, may decode the row address RA output from the row address multiplexer 724, and may activate the word line corresponding to the row address. For example, the activated row decoder may apply a word line driving voltage to a word line corresponding to the row address.

The column address latch 725 may receive the column address COL_ADDR from the address register 721, and may temporarily store the received column address COL_ADDR. Additionally, the column address latch 725 may incrementally increase the received column address COL_ADDR in a burst mode. The column address latch 725 may apply the temporarily stored or incrementally increased column address COL_ADDR to each of the plurality of column decoders 727a to 727h.

A column decoder activated by the bank control circuit 722, among the plurality of column decoders 727a to 727h, may activate a sense amplifier corresponding to the bank address BANK_ADDR and the column address COL_ADDR through a corresponding input/output gate circuit 743.

The input/output gate circuit 743 may include an input data mask logic, read data latches for storing data output from the plurality of memory core circuits 741a to 741h, write drivers for writing data to the plurality of memory core circuits 741a to 741h, along with circuits for gating input/output data.

A data signal DQ to be read from one of the bank arrays of the plurality of memory core circuits 741a to 741h may be sensed by a sense amplifier corresponding to the one bank array, and may be stored in the read data latches. The data signal DQ stored in the read data latches may be provided to the memory controller along with a data strobe signal (DQS).

The data signal DQ to be written to the memory cell array MCA included in one of the plurality of memory core circuits 741a to 741h may be provided to the input/output gate circuit 743 by the data input/output buffer 750. The input/output gate circuit 743 may write the data signal DQ to a target page of the one memory cell array MCA through the write drivers.

The data input/output buffer 750 may provides the data signal DQ to the input/output gate circuit 743 in a write operation, and may provide the data signal DQ provided from the input/output gate circuit 743 to the memory controller in a read operation.

The control logic circuit 710 may control an operation of the memory device 700. For example, the control logic circuit 710 may generate control signals so that the memory device 700 may performs the write operation or the read operation. The control logic circuit 710 may include a command decoder 711 for decoding a command CMD received from a memory controller 700 and a mode register 712 for setting an operation mode of the memory device 700.

For example, the command decoder 711 may decode a write enable signal, a row address strobe signal, a column address strobe signal, a chip select signal, or the like, thus generating the control signals corresponding to the command CMD.

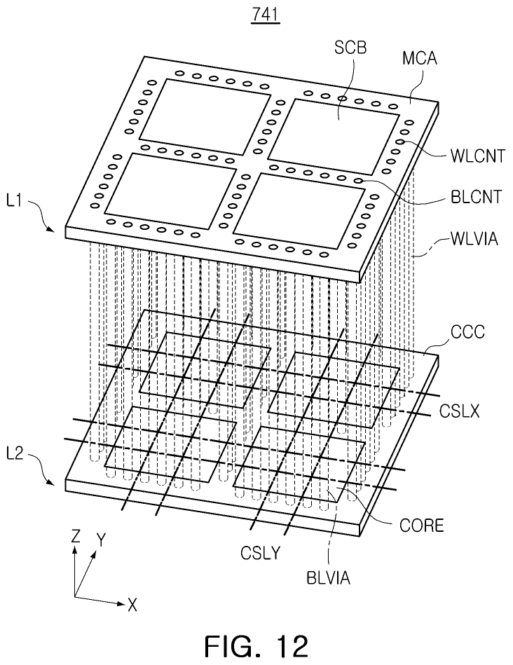

FIG. 12 is a view illustrating an example of a memory bank of FIG. 11.

FIG. 12 illustrates a first semiconductor layer L1 including a memory cell array MCA and a second semiconductor layer L2 including a core control circuit CCC. The first semiconductor layer L1 may be stacked on the second semiconductor layer L2 in a third direction (Z-direction). A structure in which the memory cell array MCA is stacked on the core control circuit CCC may be referred to as a Cell on Peri (CoP) structure.

As described with reference to FIG. 3, the memory cell array MCA may include sub-cell arrays SCB arranged in the first direction (X-direction) and the second direction (Y-direction). Core circuits CORE corresponding to each of the sub-cell arrays SCB may overlap the sub-cell arrays SCB in an X-Y plane. The core circuits CORE may include sub-word line drivers and bit line sense amplifiers as described with reference to FIG. 3.

The sub-cell arrays SCB may include a plurality of word lines extending in the first direction (X-direction) and a plurality of bit lines extending in the second direction (Y-direction), and memory cells. The memory bank 741 may include word line vias WLVIA and bit line vias BLVIA for connecting word lines and bit lines included in the sub-cell arrays SCB to the core circuits CORE. In an example of FIG. 12, it is illustrated that the word line vias WLVIA and bit line vias BLVIA extend from word line contacts WLCNT and bit line contacts BLCNT around the sub-cell arrays SCB, but the present disclosure is not limited thereto. For example, the word line vias WLVIA and bit line vias BLVIA may extend from lower portions of the sub-cell arrays SCB.

In the second semiconductor layer L2, column selection lines for connecting the bit lines to the local input/output circuits may be disposed to intersect the core circuits CORE. When the core circuits CORE may extend only in the second direction (Y-direction), it may be difficult to arrange the plurality of bit line vias BLVIA and the column selection lines so as not to intersect each other.

According to an example embodiment of the present disclosure, a plurality of first column selection lines CSLY may extend to intersect the core circuits CORE arranged in the second direction (Y-direction), and a plurality of second column selection lines CSLY may extend to intersect the core circuits CORE arranged in the first direction (X-direction). The bit line may be connected to the local input/output line based on the first column selection signal transmitted by the first column select line CSLY and the second column selection signal transmitted by the second column select line CSLX.

According to an example embodiment of the present disclosure, the column selection lines may be disposed to be divided into the column selection lines in the first direction (X-direction) and the column selection lines in the second direction (Y-direction), so that the column selection lines may be flexibly disposed in a memory core circuit 471 having regions through which the plurality of bit line vias BLVIA and the plurality of word line vias WLVIA penetrate. Accordingly, a degree of integration of the memory device may be improved.

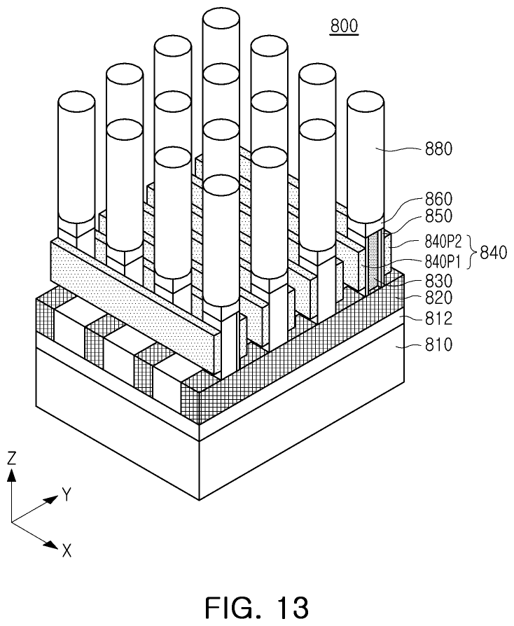

FIG. 13 is a view illustrating an example of a memory cell structure included in a sub-cell block according to an example embodiment of the present disclosure.

A memory device or a memory cell including a vertical channel transistor VCT may be applied to a memory device having a CoP structure as described with reference to FIG. 12.

Referring to FIG. 13, an integrated circuit device 800 may include a substrate 810, a plurality of first conductive lines 820, a channel layer 830, a gate electrode 840, and a capacitor structure 880. The integrated circuit device 800 may be a memory device including a vertical channel transistor VCT. The vertical channel transistor may refer to a structure in which a channel length of a channel layer 830 extends vertically from the substrate 810.

A lower insulating layer 812 may be disposed on the substrate 810, and a plurality of first conductive lines 820 may be spaced apart from each other in the first direction (X-direction) and may extend in the second direction (Y-direction) on the lower insulating layer 812. The plurality of first conductive lines 820 may function as bit lines of the integrated circuit device 800.

In an example embodiment, the plurality of first conductive lines 820 may include doped polysilicon, a metal, a conductive metal nitride, a conductive metal silicide, a conductive metal oxide, or combinations thereof. For example, the plurality of first conductive lines 820 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited thereto. The plurality of first conductive lines 820 may include a single layer or multiple layers of the above-described materials. In example embodiments, the plurality of first conductive lines 820 may include a two-dimensional semiconductor material, and may include, for example, graphene, carbon nanotubes, or combinations thereof.

The channel layers 830 may be arranged on a plurality of first conductive lines 820 in a matrix form in which the channel layers 830 are spaced apart from each other in the first direction (X-direction) and the second direction (Y-direction). The channel layer 830 may have a first width in the first direction (X-direction) and a first height in the third direction (Z direction), and the first height may be greater than the first width. For example, the first height may be about 2 to 10 times the first width, but the present disclosure is not limited thereto. A bottom portion of the channel layer 830 may function as a first source/drain region (not illustrated), and an upper portion of the channel layer 830 may function as a second source/drain region (not illustrated), and a portion of the channel layer 830 between the first and second source/drain regions may function as a channel region (not shown).

In example embodiments, the channel layer 830 may include an oxide semiconductor, for example, the oxide semiconductor may include InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or combinations thereof. The channel layer 830 may include a single layer or multiple layers of the oxide semiconductor. In some examples, the channel layer 830 may have a bandgap energy greater than a bandgap energy of silicon. For example, the channel layer 830 may have a bandgap energy of about 1.5 eV to 5.6 eV. For example, the channel layer 830 may have optimal channel performance when the channel layer 830 has the band gap energy of about 2.0 eV to 4.0 eV. For example, the channel layer 830 may be polycrystalline or amorphous, but is not limited thereto. In example embodiments, the channel layer 830 may include a two-dimensional semiconductor material, and the two-dimensional semiconductor material may include, for example, graphene, carbon nanotubes, or combinations thereof.

The gate electrode 840 may extend in the first direction (X-direction) on both sidewalls of the channel layer 830. The gate electrode 840 may include a first sub-gate electrode 840P1 facing a first sidewall of the channel layer 830 and a second sub-gate electrode 840P2 facing a second sidewall opposite to the first sidewall of the channel layer 830. As one channel layer 830 is disposed between the first sub-gate electrode 840P1 and the second sub-gate electrode 840P2, the integrated circuit device 800 may have a dual-gate transistor structure. However, the technical concept of the present disclosure is not limited thereto, and the second sub-gate electrode 840P2 may be omitted and only the first sub-gate electrode 840P1 facing the first sidewall of the channel layer 830 may be formed, thereby implementing a single-gate transistor structure.

The gate electrode 840 may include doped polysilicon, a metal, a conductive metal nitride, a conductive metal silicide, a conductive metal oxide, or combinations thereof. For example, the gate electrode 840 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited thereto.

A gate insulating layer 850 may surround a sidewall of the channel layer 830 and may be interposed between the channel layer 830 and the gate electrode 840. For example, as illustrated in FIG. 13, an entire sidewall of the channel layer 830 may be surrounded by the gate insulating layer 850, and a portion of the sidewall of the gate electrode 840 may be in contact with the gate insulating layer 850. In other example embodiments, the gate insulating layer 850 may extend in an extension direction of the gate electrode 840 (e.g., the first direction (X-direction)), and only two sidewalls of the channel layer 830 facing the gate electrode 840 may be in contact with the gate insulating layer 850.

In example embodiments, the gate insulating layer 850 may be formed of a silicon oxide film, a silicon oxynitride film, a high-κ dielectric film having a dielectric constant higher than that of the silicon oxide film, or combinations thereof. The high-κ dielectric film may be formed of a metal oxide or a metal oxynitride. For example, a high-κ dielectric film usable as the gate insulating layer 850 may be formed of HfO₂, HfSiO, HfSiON, HfTaO, HfTiO, HfZrO, ZrO₂, Al₂O₃, or combinations thereof, but the present disclosure is not limited thereto.

A capacitor contact 860 may be disposed on the channel layer 830. The capacitor contact 860 may be disposed to vertically overlap the channel layer 830, and the capacitor contacts 860 may be arranged in a matrix form in which the capacitor contact 860 are spaced apart from each other in the first direction (X-direction) and the second direction (Y-direction). The capacitor contact 860 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the present disclosure is not limited thereto.

The capacitor structure 880 may be included on the capacitor contact 860. The capacitor structure 880 may include a lower electrode, an upper electrode, and a dielectric layer between the lower electrode and the upper electrode.

The lower electrode may be electrically connected to an upper surface of the capacitor contact 860. The lower electrode may be formed in a pillar type extending in the third direction (Z-direction), but the present disclosure is not limited thereto. In example embodiments, the lower electrode may be disposed to vertically overlap the capacitor contact 860, and the lower electrodes may be arranged in a matrix form in which the lower electrodes are spaced apart from each other in the first direction (X-direction) and the second direction (Y-direction). Alternatively, a landing pad (not illustrated) may be further disposed between the capacitor contact 860 and the lower electrode, so that the lower electrodes may be arranged in a hexagonal shape.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A memory device, comprising:
a memory cell array including a plurality of word lines extending in a first direction and a plurality of bit lines extending in a second direction, intersecting the first direction, and a plurality of memory cells connected to the plurality of word lines and the plurality of bit lines;
local input/output lines transmitting a potential transmitted through selected bit lines among the plurality of bit lines to bit line sense amplifiers;
input/output gate regions including first and second column selection transistors connected to each of the plurality of bit lines and a corresponding local input/output line among the local input/output lines in series;
a plurality of first column selection lines respectively connected to gates of first column selection transistors corresponding to a plurality of bit line groups and extending in the second direction;
a second reference column selection line respectively connected to gates of second column selection transistors corresponding to a first bit line group among the plurality of bit line groups, and extending in the first direction; and
a second complementary column selection line respectively connected to gates of second column selection transistors corresponding to a second bit line group among the plurality of bit line groups, and extending in the first direction.

2. The memory device of claim 1, further comprising:
a first address decoder decoding a row address and outputting a word line selection signal to one of the plurality of word lines, and decoding an address of one bit of a column address and outputting a second column selection signal to the second reference column selection line or the complementary second column selection line; and
a second address decoder decoding an address of remaining bits of the column address and outputting a first column selection signal to one of the plurality of first column selection lines.

3. The memory device of claim 2,
wherein one bit of the column address is a Least Significant Bit (LSB).

4. The memory device of claim 1,
wherein the local input/output lines extend in the first direction.

5. The memory device of claim 1,
wherein the local input/output lines intersect a plurality of column selection switches each of which includes the first and second column selection transistors in a plane defined in the first direction and the second direction.

6. The memory device of claim 1,
wherein the plurality of first column selection lines intersect the memory cell array in a plane defined in the first direction and the second direction.

7. The memory device of claim 1,
wherein the second reference column selection line and the second complementary column selection line intersect a plurality of column selection switches each of which includes the first and second column selection transistors in a plane defined in the first direction and the second direction.

8. A memory device, comprising:
a memory cell array region including a plurality of word lines extending in a first direction and a plurality of bit lines extending in a second direction, intersecting the first direction, and a plurality of memory cells connected to the plurality of word lines and the plurality of bit lines; and
an input/output gate region for transmitting a potential transmitted through selected bit lines among the plurality of bit lines to local input/output lines,
wherein the input/output gate region includes:
a plurality of active regions arranged in the first direction and the second direction;
a plurality of first gate structures including a first main pattern spaced apart from the plurality of active regions in the second direction and extending in the first direction, and first finger patterns arranged in the first direction and extending so as to intersect the active regions arranged in the second direction;
a plurality of second gate structures including a second main pattern spaced apart in an opposite direction from the first main pattern based on the plurality of active regions and extending in the first direction, and a plurality of second finger patterns respectively extending so as to intersect the active regions arranged in the second direction and adjacent to one first finger pattern in the first direction;
a plurality of contacts electrically connecting each of the plurality of bit lines to an active region in a direction opposite to a direction of the second finger patterns, based on the first finger patterns;
a plurality of local input/output lines electrically connected to an active region in a direction opposite to a direction of the first finger patterns, based on the second finger patterns;
a plurality of first column selection lines respectively extending in the second direction and connected to each of the plurality of first gate structures; and
a plurality of second column selection lines respectively extending in the first direction and connected to each of the plurality of second gate structures.

9. The memory device of claim 8,
wherein in each of the plurality of active regions, a length thereof in the first direction is greater than a length thereof in the second direction.

10. The memory device of claim 8,
wherein the plurality of second gate structures are arranged so that two second gate structures surround first finger patterns of one first gate structure.

11. The memory device of claim 10,
wherein the plurality of second column selection lines include a second reference column selection line and a second complementary column selection line, and
one second gate structure of the two second gate structures is connected to the second reference column selection line, and the other second gate structure is connected to the second complementary column selection line.

12. The memory device of claim 10,
wherein each of the plurality of first gate structures includes four first finger patterns, and
each of the plurality of second gate structures includes two second finger patterns.

13. The memory device of claim 8,
wherein the plurality of local input/output lines extend in the first direction in the input/output gate region.

14. The memory device of claim 13,
wherein the plurality of local input/output lines and the plurality of second column selection lines are disposed in a metal layer on the same level.

15. The memory device of claim 13,
wherein the plurality of first column selection lines are disposed in a metal layer on a level higher than a level of the plurality of local input/output lines and the plurality of second column selection lines.

16. The memory device of claim 13,
wherein the plurality of bit lines are disposed in a metal layer on a level lower than a level of the plurality of local input/output lines and the plurality of second column selection lines.

17. The memory device of claim 8,
wherein the plurality of first column selection lines extend so as to intersect the input/output gate region and the memory cell array region.

18. The memory device of claim 8,
wherein the plurality of second column selection lines extend so as to intersect the input/output gate region.

19. A memory device, comprising:
a memory cell array including a plurality of word lines extending in a first direction and a plurality of bit lines extending in a second direction, intersecting the first direction, and a plurality of memory cells connected to the plurality of word lines and the plurality of bit lines; and
an input/output gate region for transmitting a potential transmitted through selected bit lines among the plurality of bit lines to bit line sense amplifiers,
wherein the input/output gate region includes:
a plurality of active regions arranged in the first direction and the second direction;
a plurality of first gate structures including a first main pattern extending in the second direction around the plurality of active regions, and branch patterns connected to the first main pattern and arranged in the second direction and extending so as to intersect the active regions arranged in the first direction;
a plurality of second gate structures including a second main pattern extending in the second direction around the plurality of active regions, and a plurality of finger patterns connected to the second main pattern and extending in the first direction and arranged in the second direction, and extending so as to intersect the active regions adjacent to one branch pattern in the second direction and arranged in the first direction;
a plurality of contacts electrically connecting each of the plurality of bit lines to an active region in a direction opposite to a direction of the finger patterns, based on the first branch pattern;
a plurality of local input/output lines electrically connected to an active region in a direction opposite to a direction of the first branch pattern, based on the finger patterns;
a plurality of first column selection lines respectively extending in the second direction and connected to each of the plurality of first gate structures; and
a plurality of second column selection lines respectively extending in the first direction and connected to each of the plurality of second gate structures.

20. The memory device of claim 19,
wherein in each of the plurality of active regions, a length thereof in the second direction is longer than a length thereof in the first direction.
